(19) United States
(12) Patent Application Publication
(10) Pub. No.: US 2020/0098562 A1
(43) Pub. Date: Mar. 26, 2020

(54) DUAL FREQUENCY SILANE-BASED SILICON DIOXIDE DEPOSITION TO MINIMIZE FILM INSTABILITY

(71) Applicant: LAM RESEARCH CORPORATION, Fremont, CA (US)

(72) Inventors: Joseph Wei, Portland, OR (US); Boyi Hao, Tigard, OR (US); Pragati Kumar, Beaverton, OR (US)

(21) Appl. No.: 16/142,370

(22) Filed: Sep. 26, 2018

(51) Int. Cl. H01L 21/02; H01J 37/32; C23C 16/40; C23C 16/505

(52) U.S. Cl. CPC H01L 21/02164; H01L 21/02274; H01L 21/02211; H01J 37/3244; H01J 37/32091; C23C 16/505; H01J 2237/3321; H01J 2237/3328; C23C 16/402

(57) ABSTRACT

A method for performing plasma enhanced chemical vapor deposition (PECVD) using a dual frequency process to deposit a silane-based oxide film on a substrate includes arranging the substrate on a substrate support in a processing chamber configured to perform PECVD and supplying PECVD process gases into the processing chamber. The process gases include a first process gas including silicon and a second process gas including an oxidant. The method further includes, while supplying the PECVD process gases into the processing chamber, generating a dual frequency plasma within the processing chamber to deposit the silane-based oxide film on the substrate by supplying a first radio frequency (RF) voltage to the processing chamber, and supplying a second RF voltage to the processing chamber. The first RF voltage is supplied at a first frequency and the second RF voltage is supplied at a second frequency that is different than the first frequency.

### FIELD

The present disclosure relates to deposition of silane-based oxide films in semiconductor substrate processing.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), and/or other deposition processes. During deposition, the substrate is arranged on a substrate support and one or more precursor gases may be supplied to a processing chamber during one or more process steps. In a PECVD process, plasma is used to activate chemical reactions within the processing chamber during deposition.

### SUMMARY

A method for performing plasma enhanced chemical vapor deposition (PECVD) using a dual frequency process to deposit a silane-based oxide film on a substrate includes arranging the substrate on a substrate support in a processing chamber configured to perform PECVD and supplying PECVD process gases into the processing chamber. The process gases include a first process gas including silicon and a second process gas including an oxidant. The method further includes, while supplying the PECVD process gases into the processing chamber, generating a dual frequency plasma within the processing chamber to deposit the silane-based oxide film on the substrate by supplying a first radio frequency (RF) voltage to the processing chamber, and supplying a second RF voltage to the processing chamber. The first RF voltage is supplied at a first frequency and the second RF voltage is supplied at a second frequency that is different than the first frequency.

In other features, the first process gas includes silane (SiH₄). The second process gas includes nitrous oxide (N₂O). The first process gas is supplied at a flow rate of 0.1 to 1.5 sccm/cm². The second process gas is supplied at a flow rate of 0.1 to 20 sccm/cm². The process gases further include an inert gas. The inert gas includes at least one of helium and argon.

In other features, the process gases further include nitrogen (N₂). The first frequency is greater than the second frequency. The first frequency is between 12 and 15 MHz and the second frequency is between 350 and 450 KHz. The first RF voltage and the second RF voltage are supplied at a same time. The first RF voltage and the second RF voltage are supplied in alternating periods. The first RF voltage and the second RF voltage are pulsed.

A system configured to perform plasma enhanced chemical vapor deposition (PECVD) using a dual frequency process to deposit a silane-based oxide film on a substrate includes a gas delivery system configured to supply PECVD process gases into a processing chamber while a substrate is arranged on a substrate support within the processing chamber. The process gases include a first process gas including silicon and a second process gas including an oxidant. The system further includes a controller configured to control a radio frequency (RF) generating system to generate, while the PECVD process gases are supplied into the processing chamber, a dual frequency plasma within the processing chamber to deposit the silane-based oxide film on the substrate by supplying a first radio frequency (RF) voltage to the processing chamber and supplying a second RF voltage to the processing chamber. The first RF voltage is supplied at a first frequency and the second RF voltage is supplied at a second frequency that is different than the first frequency.

In other features, the first process gas includes silane (SiH₄). The second process gas includes nitrous oxide (N₂O). The first process gas is supplied at a flow rate of 0.1 to 1.5 sccm/cm² and the second process gas is supplied at a flow rate of 0.1 to 20 sccm/cm². The process gases further include an inert gas. The first frequency is greater than the second frequency. The first RF voltage and the second RF voltage are supplied in alternating periods.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIG. 2 is a functional block diagram of a substrate processing system including an example of a dual frequency RF generating system according to the present disclosure;

FIG. 3 illustrates steps of an example method for performing a dual frequency PECVD process according to the present disclosure; and

FIGS. 4A, 4B, and 4C illustrate examples of the supply of dual frequency RF power to a processing chamber during a dual frequency PECVD process.

In the drawings, reference numbers may be reused to identify similar and/or identical elements.

### DETAILED DESCRIPTION

A plasma enhanced chemical vapor deposition (PECVD) process may be used to deposit a film (e.g., an amorphous film, blanket film, conformal film, etc.) on a substrate and/or an underlying layer of a semiconductor device. For example, the film may be deposited on an underlying layer during the manufacturing of a microelectromechanical systems (MEMS) device.

The deposited film has an associated mechanical stress (e.g., a tensile/compressive stress), which may be measured in megapascals (MPa). The stress of the film corresponds to a resistance of the film to physical damage (e.g., fracturing) and is indicative of electrical characteristics and reliability of the semiconductor device. Some films, such as silane (SiH₄)-based oxide films (i.e., oxide films, such as silicon dioxide (SiO₂) films, deposited via oxidation of a silane-based precursor), may be susceptible to stress drift over time subsequent to processing. Stress drift refers to changes in the mechanical stress of the film. For example, the stress drift of a silane-based oxide film may reach as high as 70 MPa within 120 hours of the deposition of the film. In some examples, deposited films may be susceptible to stress drift (i.e., instability) caused by absorption of moisture from the atmosphere and/or other environmental factors. Deposited films may also be susceptible to drift of other film properties, such as refractive index (RI) drift.

Silane-based oxide film deposition systems and methods according to the principles of the present disclosure implement a dual frequency deposition process to minimize stress and RI drift in deposited films. For example, silane-based oxide films are typically deposited using a single frequency (e.g., high frequency) PECVD process. Various post processing steps, such as an annealing step, may be used to minimize film property drift. However, these post processing steps increase fabrication cost and time. Conducting the silane-based oxide film deposition process using the dual (e.g., high and low) frequency process according to the present disclosure minimizes film property drift without performing additional post processing steps as described below in more detail.

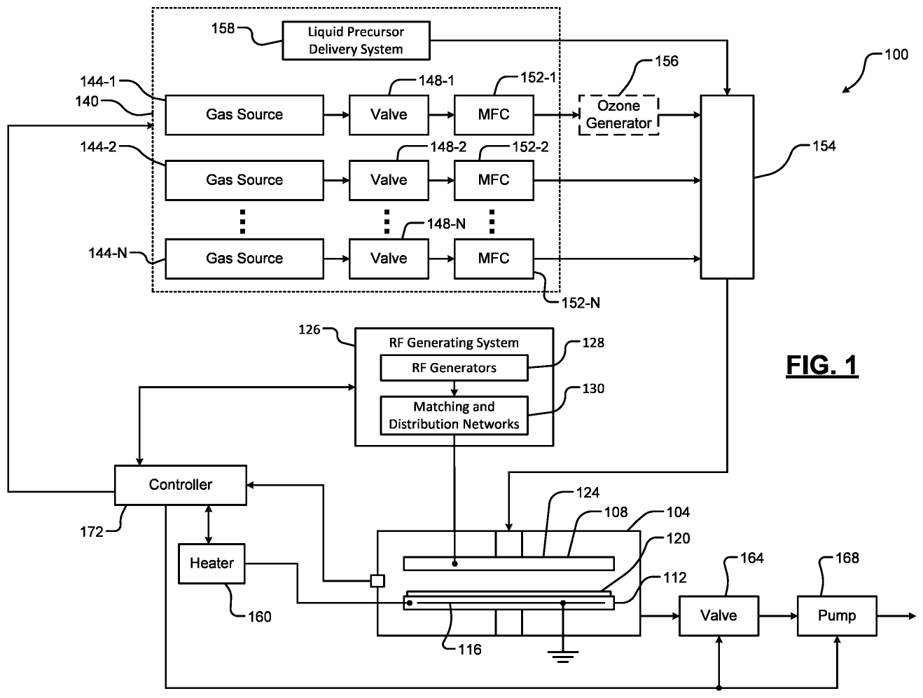

Referring now to FIG. 1, an example of a substrate processing system 100 for performing dual frequency PECVD of a silane-based oxide film according to the principles of the present disclosure is shown. While the foregoing example relates to PECVD systems, other plasma-based substrate processing chambers may be used. The substrate processing system 100 includes a processing chamber 104 that encloses other components of the substrate processing system 100. The substrate processing system 100 includes an upper electrode 108 and a substrate support such as a pedestal 112 including a lower electrode 116. A substrate 120 is arranged on the pedestal 112 between the upper electrode 108 and the lower electrode 116.

For example only, the upper electrode 108 may include a showerhead 124 that introduces and distributes process gases. Alternately, the upper electrode 108 may include a conducting plate and the process gases may be introduced in another manner. The lower electrode 116 may be arranged in a non-conductive pedestal. Alternately, the pedestal 112 may include an electrostatic chuck that includes a conductive plate that acts as the lower electrode 116.

A radio frequency (RF) generating system 126 generates and outputs an RF voltage to one of the upper electrode 108 and the lower electrode 116 when plasma is used. The other one of the upper electrode 108 and the lower electrode 116 may be DC grounded, AC grounded or floating. As shown, the RF voltage is output to the upper electrode 108 and the lower electrode 116 is grounded. For example only, the RF generating system 126 may include one or more RF voltage generators 128 (e.g., a capacitively-coupled plasma RF power generator, a bias RF power generator, and/or other RF power generator) that generate RF voltages, which are fed by one or more matching and distribution networks 130 to the upper electrode 108 (as shown) and/or the lower electrode 116.

An example gas delivery system 140 includes one or more gas sources 144-1, 144-2, . . . , and 144-N (collectively gas sources 144), where N is an integer greater than zero. The gas sources 144 supply one or more gases (e.g., precursors, inert gases, etc.) and mixtures thereof. Vaporized precursor may also be used. At least one of the gas sources 144 may contain gases used in the pre-treatment process of the present disclosure (e.g., NH₃, N₂, etc.). The gas sources 144 are connected by valves 148-1, 148-2, . . . , and 148-N (collectively valves 148) and mass flow controllers 152-1, 152-2, . . . , and 152-N (collectively mass flow controllers 152) to a manifold 154. An output of the manifold 154 is fed to the processing chamber 104. For example only, the output of the manifold 154 is fed to the showerhead 124. In some examples, an optional ozone generator 156 may be provided between the mass flow controllers 152 and the manifold 154. In some examples, the substrate processing system 100 may include a liquid precursor delivery system 158. The liquid precursor delivery system 158 may be incorporated within the gas delivery system 140 as shown or may be external to the gas delivery system 140. The liquid precursor delivery system 158 is configured to provide precursors that are liquid and/or solid at room temperature via a bubbler, direct liquid injection, vapor draw, etc.

A heater 160 may be connected to a heater coil (not shown) arranged in the pedestal 112 to heat the pedestal 112. The heater 160 may be used to control a temperature of the pedestal 112 and the substrate 120. A valve 164 and pump 168 may be used to evacuate reactants from the processing chamber 104. A controller 172 may be used to control various components of the substrate processing system 100. For example only, the controller 172 may be used to control flow of process, carrier and precursor gases, striking and extinguishing plasma, removal of reactants, monitoring of chamber parameters, etc. The controller 172 according to the principles of the present disclosure is further configured to control the RF generators 128 to implement the dual frequency PECVD process as described below in more detail.

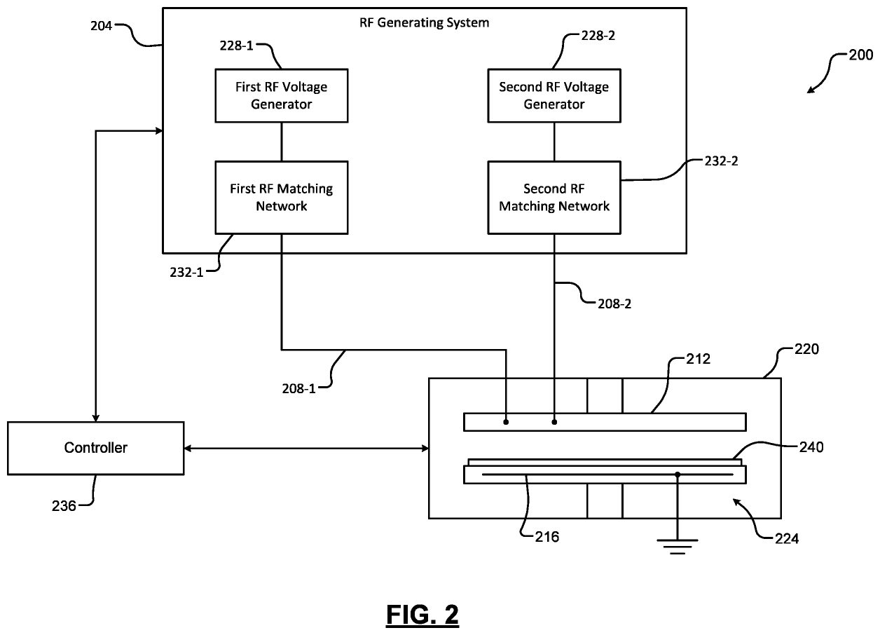

Referring now to FIG. 2, an example of a substrate processing system 200 including an RF generating system 204 configured to perform dual frequency PECVD according to the principles of the present disclosure is shown. In this example, the RF generating system 204 is configured for generating capacitively-coupled, dual frequency plasma. The radio frequency RF generating system 204 generates and outputs a first RF voltage 208-1 and a second RF voltage 208-2 (referred to collectively as RF voltages 208) to one of an upper electrode 212 and a lower electrode 216 within a processing chamber 220. For example, the upper electrode 212 corresponds to a gas distribution device (e.g., a showerhead) and the lower electrode 216 corresponds to a substrate support 224. As shown, the first and second RF voltages are output to the upper electrode 212 and the lower electrode 216 is grounded.

The RF generating system 204 includes a first RF voltage generator 228-1 and a second RF voltage generator 228-2, referred to collectively as RF voltage generators 228. The first RF voltage generator 228-1 provides the first RF voltage 208-1 to a first RF matching network 232-1. The second RF voltage generator 228-2 provides the second RF voltage 208-2 to a second RF matching network 232-2. The first RF matching network 232-1 and the second RF matching network 232-2, referred to collectively as RF matching networks 232, feed the RF voltages 208 to the upper electrode 212. In other examples, the second RF voltage generator 228-2 may correspond to a bias RF voltage generator configured to output an RF voltage to the lower electrode 216.

The first RF voltage generator 228-1 and the second RF voltage generator 228-2 according to the present disclosure are configured to output dual frequency RF voltages during a PECVD process responsive to a controller 236 (e.g, corresponding to the controller 172 of FIG. 1). For example, the controller 236 is configured to control the first RF voltage generator 228-1 to output the first RF voltage 208-1 at a first frequency and the second RF voltage generator 228-2 to output the second RF voltage 208-2 at a second frequency during deposition of a silane-based oxide film. For example, the first RF voltage 208-1 may provide high frequency RF power (e.g., 0.1 to 4.0 watts/cm² at 12-15 MHz) and the second RF voltage 208-2 may provide low frequency RF power (e.g., 0.1 to 2.0 watts/cm² at 350-450 KHz) while process gases are introduced into the processing chamber 220 to generate plasma for the PECVD process and deposit the silane-based oxide film on a substrate 240.

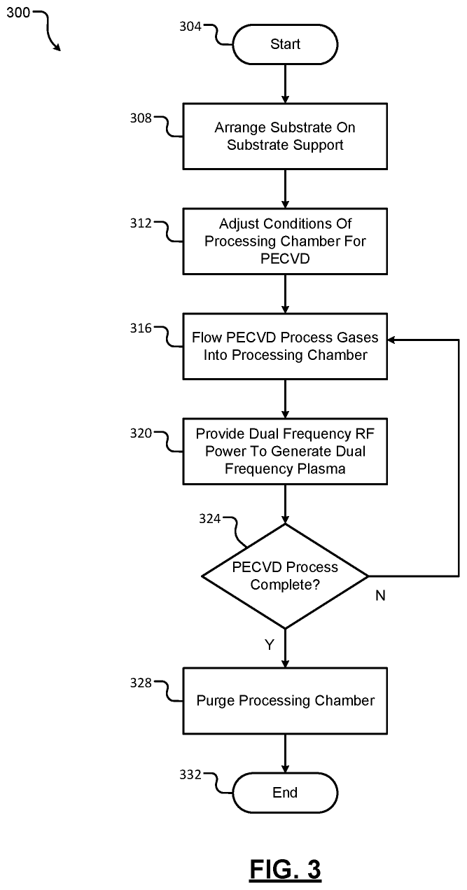

Referring now to FIG. 3 and with continued reference to FIG. 2, a method 300 for performing a dual frequency PECVD process to deposit a silane-based oxide film begins at 304. At 308, a substrate is arranged on a substrate support (e.g., the substrate support 224) in a processing chamber (e.g., the processing chamber 220. For example, the substrate may correspond to a silicon substrate. In other examples, the substrate may include sapphire, glass, piezoelectric material, etc. In some examples, the substrate may include one or more underlying layers. At 312, the method 300 (e.g., the controller 236) adjusts conditions of the processing chamber 200 to conditions suitable for performing PECVD of the silane-based oxide film. For example, the processing chamber 200 is adjusted to a pressure of 1 to 9 torr and to a temperature of 100 to 450° C.

At 316, the method 300 flows process gases (e.g., one or more precursor gases, carrier gases, inert gases, etc.) into the processing chamber 220. For example, the controller 236 controls flow of process gases from respective gas sources (e.g., the gas sources 144 of the gas delivery system 140) into the processing chamber 220. The process gases include a silicon-containing gas compound (e.g., silane (SiH₄)) and an oxidant (e.g., nitrous oxide (N₂O), molecular oxygen (O₂), ozone (O₃), etc.). The controller 236 is configured to control the flow of silane at a rate of 0.1 to 1.5 sccm/cm² and the flow of the oxidant at a rate of 0.1 to 20 sccm/cm² during the deposition process. In some examples, the controller 236 may also control a flow of nitrogen (N₂, at an example rate of 3 to 16 sccm/cm²) and an inert gas (e.g., helium (He), argon (Ar), etc., at an example rate of 3 to 16 sccm/cm²) into the processing chamber 200. For example, providing the inert gas during the deposition process may further minimize stress drift.

At 320, the method 300 (e.g., the controller 236 and the RF generating system 204) provides dual frequency RF power to the processing chamber 220 to generate dual frequency plasma within the processing chamber 200. For example, the method 300 outputs a first RF voltage and a second RF voltage to generate the dual frequency plasma. In one example, the first RF voltage corresponds to high frequency RF power (e.g., 0.1 to 4.0 watts/cm² at 12-15 MHz) and the second RF voltage corresponds to low frequency RF power (e.g., 0.1 to 2.0 watts/cm² at 350-450 KHz). For example, a first frequency of the high frequency RF power is approximately 13.56 MHz (e.g., +/−0.5 MHz) and a second frequency of the low frequency RF power is 400 KHz (e.g., +/−30 KHz). The dual frequency RF power is provided while the process gases are introduced into the processing chamber 220 in accordance with step 316 to perform the PECVD process and deposit the silane-based oxide film on the substrate.

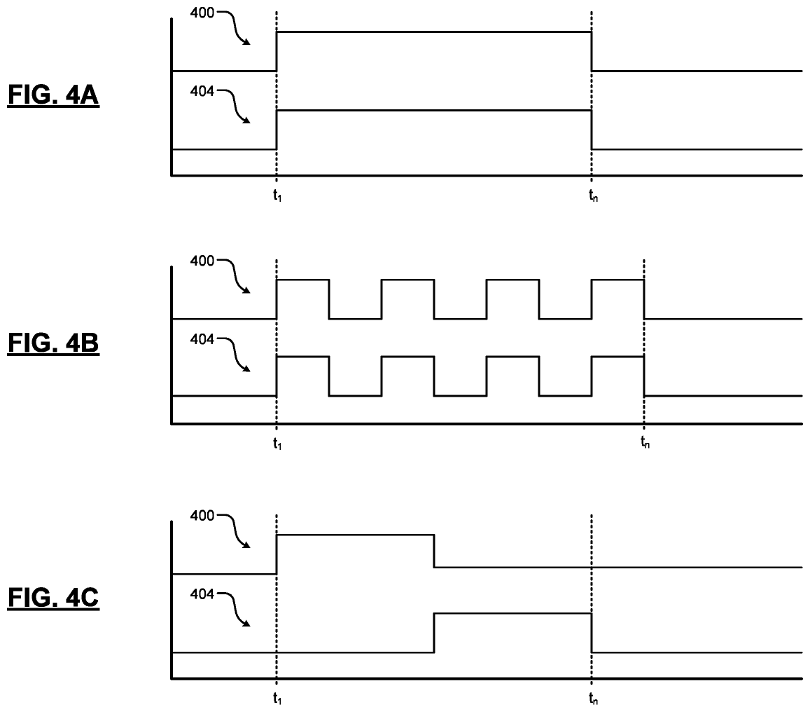

In some examples, the first RF voltage and the second RF voltage are output simultaneously and continuously for a total duration of the PECVD process. In other words, with reference to FIG. 4A, a first RF voltage 400 and a second RF voltage 404 are each supplied at a same time and in a same period (e.g., from a time t₁ to a time tₙ corresponding to an end of the PECVD process). In another example, the first RF voltage 400 and the second RF voltage 404 are supplied in the same period but are non-continuous (i.e., pulsed ON and OFF as shown in FIG. 4B). Although as shown in FIG. 4B the first RF voltage 400 and the second RF voltage 404 are pulsed ON at a same time and OFF at a same time, in other examples the first RF voltage 400 and the second RF voltage 404 may be pulsed ON in alternating periods. In another example, the first RF voltage 400 is continuously supplied in a first portion of the duration of the PECVD process and the second RF voltage 404 is continuously supplied in a second portion of the duration of the PECVD process as shown in FIG. 4C. In other words, the first RF voltage 400 and the second RF voltage 404 are supplied in non-overlapping portions of the PECVD process.

At 324, the method 300 (e.g., the controller 236) determines whether the PECVD process is complete. For example, the PECVD process may have a duration of 1 to 1000 ms. In some examples, the PECVD process is performed at a same station of a substrate processing system. In other examples, the PECVD process is performed at multiple stations (e.g., for 1 to 250 ms at each of 4 stations) of a substrate processing system. If the result of 324 is true, the method 300 continues to 328. If the result of 324 is false, the method 300 continues to 316. At 328, the method 300 (e.g., the controller 236, controlling the valve 164 and the pump 168 as described in FIG. 1) purges the processing chamber 220. The method 300 ends at 332.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for performing plasma enhanced chemical vapor deposition (PECVD) using a dual frequency process to deposit a silane-based oxide film on a substrate, the method comprising:
arranging the substrate on a substrate support in a processing chamber configured to perform PECVD;
supplying PECVD process gases into the processing chamber, wherein the process gases include a first process gas including silicon and a second process gas including an oxidant; and
while supplying the PECVD process gases into the processing chamber, generating a dual frequency plasma within the processing chamber to deposit the silane-based oxide film on the substrate by
supplying a first radio frequency (RF) voltage to the processing chamber, and
supplying a second RF voltage to the processing chamber,
wherein the first RF voltage is supplied at a first frequency and the second RF voltage is supplied at a second frequency that is different than the first frequency.

2. The method of claim 1, wherein the first process gas includes silane (SiH₄).

3. The method of claim 1, wherein the second process gas includes nitrous oxide (N₂O).

4. The method of claim 1, wherein the first process gas is supplied at a flow rate of 0.1 to 1.5 sccm/cm².

5. The method of claim 1, wherein the second process gas is supplied at a flow rate of 0.1 to 20 sccm/cm².

6. The method of claim 1, wherein the process gases further include an inert gas.

7. The method of claim 6, wherein the inert gas includes at least one of helium and argon.

8. The method of claim 1, wherein the process gases further include nitrogen (N₂).

9. The method of claim 1, wherein the first frequency is greater than the second frequency.

10. The method of claim 1, wherein the first frequency is between 12 and 15 MHz and the second frequency is between 350 and 450 KHz.

11. The method of claim 1, wherein the first RF voltage and the second RF voltage are supplied at a same time.

12. The method of claim 1, wherein the first RF voltage and the second RF voltage are supplied in alternating periods.

13. The method of claim 1, wherein the first RF voltage and the second RF voltage are pulsed.

14. A system configured to perform plasma enhanced chemical vapor deposition (PECVD) using a dual frequency process to deposit a silane-based oxide film on a substrate, the system comprising:
a gas delivery system configured to supply PECVD process gases into a processing chamber while a substrate is arranged on a substrate support within the processing chamber, wherein the process gases include a first process gas including silicon and a second process gas including an oxidant; and
a controller configured to control a radio frequency (RF) generating system to generate, while the PECVD process gases are supplied into the processing chamber, a dual frequency plasma within the processing chamber to deposit the silane-based oxide film on the substrate by
supplying a first radio frequency (RF) voltage to the processing chamber, and
supplying a second RF voltage to the processing chamber,
wherein the first RF voltage is supplied at a first frequency and the second RF voltage is supplied at a second frequency that is different than the first frequency.

15. The system of claim 14, wherein the first process gas includes silane (SiH₄).

16. The system of claim 14, wherein the second process gas includes nitrous oxide (N₂O).

17. The system of claim 14, wherein the first process gas is supplied at a flow rate of 0.1 to 1.5 sccm/cm² and the second process gas is supplied at a flow rate of 0.1 to 20 sccm/cm².

18. The system of claim 14, wherein the process gases further include an inert gas.

19. The system of claim 14, wherein the first frequency is greater than the second frequency.

20. The system of claim 14, wherein the first RF voltage and the second RF voltage are supplied in alternating periods.
